(19) United States
(12) Patent Application Publication
(10) Pub. No.: US 2026/0047362 A1
(43) Pub. Date: Feb. 12, 2026

(54) METHOD OF MANUFACTURING SEMICONDUCTOR DEVICE

(71) Applicant: Samsung Electronics Co., Ltd., Suwon-si (KR)

(72) Inventors: Seunghwan LEE, Suwon-si (KR); Jinseong PARK, Seoul (KR); Haelin YANG, Seoul (KR); Jihyun GWOEN, Seoul (KR); Beomseok KIM, Suwon-si (KR); Sanghoon LEE, Seoul (KR); Hanjin LIM, Suwon-si (KR); Changhwa JUNG, Suwon-si (KR)

(73) Assignees: Samsung Electronics Co., Ltd., Suwon-si (KR); IUCF-HYU (Industry-University Cooperation Foundation Hanyang University), Seoul (KR)

(21) Appl. No.: 19/266,331

(22) Filed: Jul. 11, 2025

(30) Foreign Application Priority Data
Aug. 12, 2024 (KR) 10-2024-0107882

(51) Int. Cl. H01L 21/02; C23C 16/40; C23C 16/455; H10B 12/00

(52) U.S. Cl. CPC H01L 21/0228; C23C 16/405; C23C 16/45553; H01L 21/02186; H10B 12/033; H10B 12/30

(57) ABSTRACT

A method of manufacturing a semiconductor device includes may include preparing a base substrate, adsorbing a Si-based growth inhibitor, and selectively forming a metal oxide layer. The base substrate may include a growth region including TiN and a non-growth region including Si. Surfaces of the growth region and the non-growth region may be exposed. The Si-based growth inhibitor may be adsorbed on an exposed surface of the non-growth region by supplying the Si-based growth inhibitor to the base substrate. The metal oxide layer may be selectively formed on the growth region relative to the non-growth region by supplying a metal precursor and an oxidizing reactant gas to the base substrate. The selectively forming the metal oxide layer on the growth region may include forming a SiTiON layer between the surface of the growth region and the metal oxide layer.

### CROSS-REFERENCE TO RELATED APPLICATION

This application is based on and claims priority under 35 U.S.C. § 119 to Korean Patent Application No. 10-2024-0107882, filed on Aug. 12, 2024, in the Korean Intellectual Property Office, the disclosure of which is incorporated by reference herein in its entirety.

### BACKGROUND

Inventive concepts relate to a method of manufacturing a semiconductor device, and more particularly, to a method of manufacturing a semiconductor device including a capacitor.

With the development of electronics technology, the down-scaling of semiconductor devices has been rapidly progressing. Accordingly, an area occupied by patterns in a semiconductor device may become very small, and also, the spacing between the patterns may become very narrow. In particular, as the patterns of lower electrodes of capacitors in semiconductor memory devices become finer, semiconductor devices including supports for the patterns of the lower electrodes have been developed to limit and/or prevent the collapse of the lower electrodes. Regarding such semiconductor devices, there may be a need for a method to effectively form a dielectric layer on the lower electrodes through a simple process.

### SUMMARY

Inventive concepts provide a method of manufacturing a semiconductor device through a simple process.

Inventive concepts provide a method of manufacturing a semiconductor device including a capacitor through a simple process and/or a semiconductor device manufactured by using the same.

According to an embodiment of inventive concepts, a method of manufacturing a semiconductor device may include preparing a base substrate, the base substrate including a growth region comprising TiN and a non-growth region comprising Si, a surface of the growth region being exposed, and a surface of the non-growth region being exposed; adsorbing a Si-based growth inhibitor on the surface of the non-growth region by supplying the Si-based growth inhibitor to the base substrate; and selectively forming a metal oxide layer on the growth region relative to the non-growth region by supplying a metal precursor and an oxidizing reactant gas to the base substrate. The selectively forming the metal oxide layer on the growth region may include forming a SiTiON layer between the surface of the growth region and the metal oxide layer.

According to an embodiment of inventive concepts, a method of manufacturing a semiconductor device may include providing a structure on a base substrate in a reaction chamber, the structure including a plurality of lower electrodes and a plurality of supporters between the plurality of lower electrodes, the plurality of lower electrodes including TiN, the plurality of supporters supporting the plurality of lower electrodes, and the plurality of supporters including SiOₓ, SiNₓ, SiON, SiCN or SiOCN; adsorbing a Si-based growth inhibitor on surfaces of the plurality of supporters by supplying the Si-based growth inhibitor into the reaction chamber to provide the Si-based growth inhibitor to the structure on the base substrate, the Si-based growth inhibitor including SiPhCl₃, Si(CH₃)₃(NMe₂), (CH₃)₃SiN(CH₃)₂, SiMe₃(NMe₂), SiMe₃OEt, or SiMe₃OMe; performing hydrogenation processing on the structure on the base substrate while the Si-based growth inhibitor is adsorbed thereon by supplying a hydrogen-containing gas into the reaction chamber; selectively forming an interface layer on regions of the plurality of lower electrodes not covered by the plurality of supporters, the interface layer including a molybdenum oxide layer, the selectively forming the interface layer including sequentially supplying a molybdenum precursor and an oxidizing reactant gas into the reaction chamber while the structure on the base substrate is in the reaction chamber, and the selectively forming the interface layer including forming a SiTiON layer between the plurality of lower electrodes and the molybdenum oxide layer; forming a dielectric layer on the interface layer; and forming an upper electrode on the dielectric layer.

### BRIEF DESCRIPTION OF THE DRAWINGS

Embodiments will be more clearly understood from the following detailed description taken in conjunction with the accompanying drawings in which:

FIGS. 1A to 1C are schematic cross-sectional views conceptually illustrating a method of manufacturing a semiconductor device according to some embodiments;

FIG. 1D is a schematic cross-sectional view conceptually illustrating an aspect in a method of manufacturing a semiconductor device according to some embodiments;

FIG. 2 is a schematic flowchart to explain a method of manufacturing a semiconductor device according to some embodiments;

FIG. 3 is a graph for comparing selectivity of adsorption of growth inhibitors according to some other embodiments;

FIG. 4 is a schematic flowchart to explain a method of manufacturing a semiconductor device according to some other embodiments;

FIGS. 5A to 5C are conceptual diagrams illustrating changes in a surface state of a non-growth region due to hydrogenation processing during a method of manufacturing a semiconductor device according to some embodiments;

FIG. 6 is a graph illustrating growth selectivity when using a method of manufacturing a semiconductor device according to some embodiments;

FIG. 7 is a cross-sectional view of a semiconductor device formed according to a method of manufacturing a semiconductor device according to some embodiments;

FIG. 8 is a cross-sectional view of a semiconductor device formed according to a method of manufacturing a semiconductor device according to some other embodiments; and

FIGS. 9 to 17 are sequential cross-sectional views to explain a method of manufacturing a semiconductor device according to some embodiments.

### DETAILED DESCRIPTION OF THE EMBODIMENTS

Hereinafter, embodiments of inventive concepts will be described in detail with reference to the accompanying drawings.

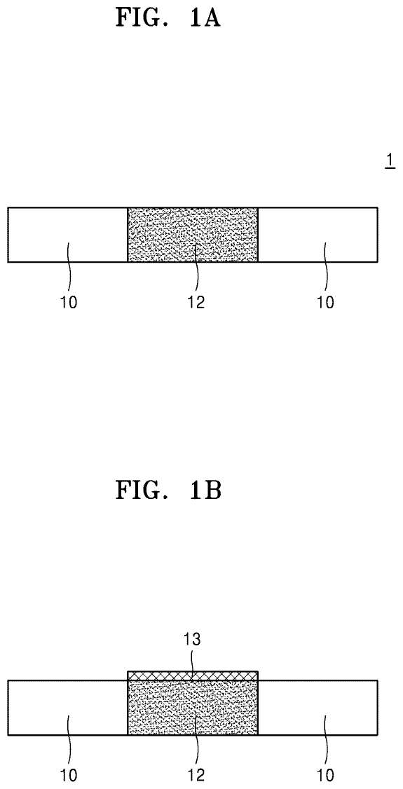

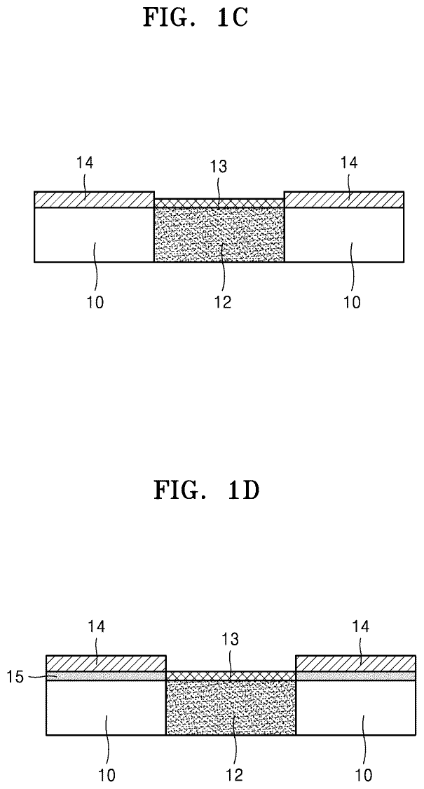

FIGS. 1A to 1C are schematic cross-sectional views conceptually illustrating a method of manufacturing a semiconductor device according to some embodiments. FIG. 1D is a schematic cross-sectional view conceptually illustrating an aspect in a method of manufacturing a semiconductor device according to some embodiments.

Referring to FIG. 1A, a base substrate 1 including a growth region 10 in which growth of a specific material layer is required and a non-growth region 12 in which the growth of the specific material layer is not required is provided. The method of manufacturing of a semiconductor device according to some embodiments involves growing a specific thin film through an atomic layer deposition (ALD) method. The ALD method is a technology in which a chemical substance referred to as a precursor, which is a raw material for a thin film, and a reactive substance, which reacts with the precursor, are alternately and sequentially supplied into a reaction space to grow an ultra-thin film on a substrate with a thickness of atomic layers in the order of angstroms. The ALD method has the advantages that the thickness of the thin film to be grown may be finely controlled and that a high-quality thin film may be uniformly applied over an entire surface exposed. However, in order to form the thin film only on a specific selected region selected among the exposed entire surface of the substrate using the ALD method, there is a disadvantage in that after the thin film is grown on the exposed entire surface of the substrate through the ALD method, and then a photolithography process and an etching process should be additionally performed to remove the thin film formed in a non-selected region. Therefore, some embodiments relate to forming a specific thin film only in a specific region by using an area selective deposition method or an area selective atomic layer deposition (AS-ALD) method that grows the thin film in the specific region in a bottom-up manner while using the ALD method.

Referring again to FIG. 1A, the growth region 10 of the base substrate 1 is a region where a specific film may be grown according to a subsequent process. There are no restrictions on a geometric structure and material characteristics of the growth region 10 as long as a specific film may be grown therein according to the subsequent process. In some embodiments, the growth region 10 may include a conductive region including, for example, a metal or a metal nitride. In some embodiments, the growth region 10 may include a transition metal or a transition metal nitride belonging to periods 4-7 and Groups 3-12 in the periodic table. In some embodiments, the growth region 10 may include a metal such as Cu, Al, or W. In some embodiments, the growth region 10 may include a nitride such as TiN or Si₃N₄.

On the other hand, the non-growth region 12 adjacent to the growth region 10 is a region where growth of a specific film is not required in the subsequent process. There are no restrictions on a geometric structure and material characteristics of the non-growth region 12 unless the specific film is grown therein according to the subsequent process. In some embodiments, the non-growth region 12 may include an insulating region. In some embodiments, the non-growth region 12 may include SiOₓ, for example SiO₂. In some other embodiments, the non-growth region 12 may include SiNₓ, SiON, SiCN or SiOCN.

Referring to FIG. 1B, a growth inhibitor 13 may be adsorbed on the non-growth region 12 to passivate an exposed surface of the non-growth region 12. The growth inhibitor 13 may be selectively adsorbed on the surface of the non-growth region 12 relative to a surface of the growth region 10. The growth inhibitor 13 may modify the surface of the non-growth region 12 to delay the adsorption of a specific precursor on the non-growth region 12, in which the specific precursor may be adsorbed on the growth region 10 in a subsequent atomic layer deposition process. On the other hand, such a selective passivation may be achieved using self-assembled monolayers (SAM) or small molecule inhibitors (SMI) precursor compounds. Compared to SAM, the SMI precursor compounds have the advantage of being rapidly deposited from a vapor phase and of being easily deposited in an ALD equipment or a chemical vapor deposition (CVD) equipment.

Thus, in some embodiments, the growth inhibitor 13 may be adsorbed using the SMI precursor. In some embodiments, a Si-based growth inhibitor precursor may be used for the growth inhibitor 13. In some embodiments, the Si-based growth inhibitor precursor may include, for example, SiPhCl₃, Si (CH₃) 3 (NMe₂), (CH₃)₃SiN (CH₃) 2, SiMe₃ (NMe₂), SiMe₃OEt, or SiMe₃OMe.

In some embodiments, the Si-based growth inhibitor precursor may include SiAₓB_{y}C_{z}Dₘ, wherein the SiAₓB_{y}C_{z}Dₘ may include one or more leaving groups and one or more inert ligands among A, B, C, and D ligands. The leaving group may include —Cl, —Br, —I, —O—R, —N—R₂, —OH, —NH₂, —SH, and the like. The inert ligand may include —R, cyclopentadienyl, phenyl, benzyl, benzonyl, and the like. On the other hand, in some embodiments, the growth inhibitor precursor may include acetylacetone, alcohol, and the like.

On the other hand, an adsorption process of the SMI precursor may be performed with a sufficient number of cycles (e.g., M cycle, M is a natural number of one or more) so that the growth inhibitor 13 may be sufficiently adsorbed on the surface of the non-growth region 12. The SMI precursors that are not adsorbed may be purged from the reaction space while supplying a purge gas, for example, an argon gas. Therefore, the supply and purging of the SMI precursor into and from the reaction space may be repeated multiple times in order to form the growth inhibitor 13 of a desired thickness.

In addition, after adsorbing the growth inhibitor 13 on the surface of the non-growth region 12, the growth inhibitor 13 or reactive groups on the surface of the non-growth region 12 may be subjected to hydrogenation processing. In some embodiments, the hydrogenation processing may be performed before adsorbing the growth inhibitor 13 thereon. In some embodiments, the hydrogenation processing may be performed both before and after adsorbing the growth inhibitor 13 thereon. The hydrogenation processing may be performed by supplying a reducing gas into the reaction space in which the base substrate 1 is provided. In some embodiments, the hydrogenation processing may be performed using H₂ gas, CCP H₂ plasma, ICP H₂ plasma, remote H₂ plasma, and the like. The details of the hydrogenation processing will be described later.

Referring to FIG. 1C, a growth material layer, for example, a metal oxide layer 14 may be grown on the growth region 10. The growth of the metal oxide layer 14 may be delayed on the growth inhibitor 13, so the metal oxide layer 14 may be selectively grown on the growth region 10 relative to the non-growth region 12. The metal oxide layer 14 may be formed by the ALD method in which a metal precursor and an oxidizing reactant gas are alternately and sequentially supplied into the reaction space provided with the base substrate 1. A step of supplying the metal precursor and a step of supplying the oxidizing reactant gas may be performed with a plurality of cycles (e.g., N cycles, wherein N is a natural number of one or more).

The metal oxide layer 14 may include an oxide layer of various metals, for example, a molybdenum oxide layer, a niobium oxide layer, a titanium oxide layer, a tantalum oxide layer, a vanadium oxide layer, a manganese oxide layer, or an yttrium oxide layer, but is not limited thereto.

In some embodiments, when the metal oxide layer 14 is a molybdenum oxide layer, the metal precursor may include the molybdenum precursor, and the molybdenum precursor may include a tetravalent precursor, a pentavalent precursor, or a hexavalent precursor. In some embodiments, the tetravalent molybdenum precursor may include MoAₓB_{y}C_{z}Dₘ (2≤x+y+z+m≤4, 0≤x, y, z, m≤4), MoAₓB_{y}C_{z}DₘEₙ (2≤x+y+z+m+n≤5, 0≤x, y, z, m, n≤5), or MoAₓB_{y}C_{z}DₘEₙFᵢ (2≤x+y+z+m+n+i≤6, 0≤x, y, z, m, n, i≤6), but is not limited thereto.

The oxidizing reactant gas may include O₃, O₂, O₂ plasma, H₂O, NO₂, NO₂ plasma, N₂O, N₂O plasma, dry air, or alcohol, but is not limited thereto.

On the other hand, in the step of forming the metal oxide layer 14 on the growth region 10, a trace amount of Si component derived from the Si-based growth inhibitor may remain between the surface of the growth region 10 and the metal oxide layer 14 in the growth region 10. In some embodiments, the content of the Si component remained between the surface of the growth region 10 and the metal oxide layer 14 in the growth region 10 may increase when the growth inhibitor 13 is formed using the Si-based growth inhibitor precursor compared to when the growth inhibitor 13 is formed without using the Si-based growth inhibitor precursor. In some embodiments, when the growth region 10 includes TiN, a SiTiON layer may be formed between the surface of the growth region 10 and the metal oxide layer 14. For example, as depicted in FIG. 1D, the SiTiON layer 15 may form between the surface of the growth region 10 and the metal oxide layer 14.

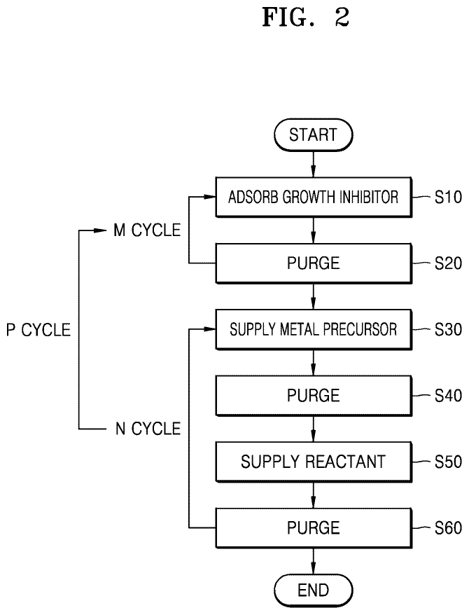

FIG. 2 is a schematic flowchart to explain a method of manufacturing a semiconductor device according to some embodiments. Referring to FIG. 2 together with FIGS. 1A to 1C, the method of manufacturing the semiconductor device according to some embodiments will be described in detail.

The base substrate 1 with exposed surfaces of the growth region 10 and the non-growth region 12 may be provided in the reaction space (not shown), for example, a reaction chamber. As described above, the growth region 10 may include a metal or a metal nitride on which a specific material layer may grow through the subsequent process. In this embodiment, the growth region 10 include TiN, but is not limited thereto. On the other hand, the non-growth region 12 may include an insulating region that does not require growth of the specific material layer through the subsequent process. In this embodiment, the non-growth region 12 includes SiO₂, but is not limited thereto.

Next, a step of adsorbing a growth inhibitor may be performed on the base substrate 1 in the reaction space (S10). The step of adsorbing the growth inhibitor may be performed by supplying a growth inhibitor precursor into the reaction space. As the growth inhibitor precursor, the SMI precursor may be used. In this embodiment, the growth inhibitor precursor may include the Si-based growth inhibitor precursor, and SiPhCl₃ (trichlorophenylsilane; TCPS) may be used as the Si-based growth inhibitor precursor, but is not limited thereto. A chemical formula of the TCPS is C₆H₅Cl₃Si and may be a compound with the chemical formula SiCl₃. The TCPS may be selectively adsorbed only on a surface of SiO₂, which is the non-growth region 12, and may be hardly adsorbed on the surface of TiN, which is the growth region 10.

Next, a step of purging may be performed, in which a purge gas, for example, an argon gas, may be supplied into the reaction space to purge unadsorbed TCPS remaining in the reaction space (S20). On the other hand, since the growth inhibitor 13 may be adsorbed on the surface of the non-growth region 12 of the base substrate 1 in atomic layer units, the step of adsorbing the growth inhibitor (S10) and the step of purging (S20) may be performed in multiple cycles (e.g., M cycles, wherein M is a natural number) so that the growth inhibitor 13 may be adsorbed on the surface of the non-growth region 12 with a sufficient thickness.

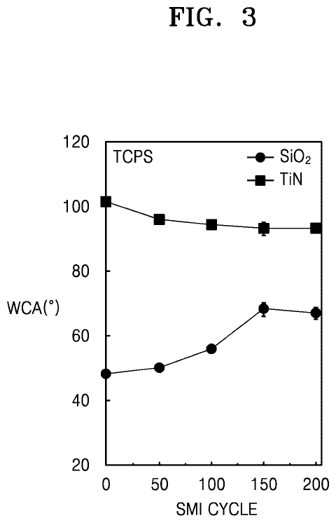

FIG. 3 shows the results of measuring a contact angle, for example, a water contact angle (WCA), on the surfaces of SiO₂ and TiN after performing the step of adsorbing the growth inhibitor S10 and the step of purging (S20) in multiple cycles using TCPS as the SMI precursor. Referring to FIG. 3, when TCPS treatment is not performed (that is, when the number of SMI cycles is zero), the water contact angle on the surface of SiO₂ is about 44.5 degrees, but the water contact angle on the surface of SiO₂ may increase as the number of SMI cycles increases. For example, when the number of SMI cycles exceeds about 100 cycles, the water contact angle may become greater than about 60 degrees. In general, the greater the contact angle on a surface of any material, the less the wettability, and therefore the surface thereof may be hydrophobic. On the other hand, the less the contact angle, the greater the wettability, and therefore the surface thereof may be hydrophilic.

On the other hand, it may be found that on the surface of TiN, the water contact angle does not increase but rather slightly decreases even as the number of SMI cycles increases. Therefore, it may be found that TCPS may be selectively adsorbed on the surface of SiO₂ relative to the surface of TiN. On the other hand, a trace amount of TCPS may be adsorbed on the surface of TiN, which is the growth region 10. Thus, a trace amount of Si component derived from the Si-based growth inhibitor may remain on the surface of TiN.

Referring again to FIG. 2, after performing the steps of adsorbing the growth inhibitor (S10) and purging (S20) are repeated by the number of M cycles, a step of supplying a metal precursor into the reaction space (S30). The metal precursor may be a raw material precursor of the metal oxide layer 14 to be grown on the growth region 10, and may include, for example, a molybdenum precursor, a niobium precursor, a titanium precursor, a tantalum precursor, a vanadium precursor, a manganese precursor, or an yttrium precursor, but is not limited thereto. In this embodiment, the metal precursor may use the molybdenum precursor, but is not limited thereto. The molybdenum precursor may include the tetravalent precursor, the pentavalent precursor, or the hexavalent precursor. In some embodiments, the tetravalent molybdenum precursor may include MoAₓB_{y}C_{z}Dₘ (2≤x+y+z+m≤4, 0≤x, y, z, m≤4), MoAₓB_{y}C_{z}DₘEₙ (2≤x+y+z+m+n≤5, 0≤x, y, z, m, n≤5), or MoAₓB_{y}C_{z}DₘEₙFᵢ (2≤x+y+z+m+n+i≤6, 0≤x, y, z, m, n, i≤6), but is not limited thereto.

The molybdenum precursor may be adsorbed on the growth region 10 of the base substrate 1 in atomic layer units, and the molybdenum precursor remaining without being adsorbed may be purged with a purge gas, for example, an argon gas (S40).

Next, a step of supplying a reactant into the reaction space may be performed (S50). The reactant may include a reactant gas, for example, an oxidizing reactant gas. The oxidizing reactant gas may include O₃, O₂, O₂ plasma, H₂O, NO₂, NO₂ plasma, N₂O, N₂O plasma, dry air, or alcohol, but is not limited thereto. In this embodiment, O₂ may be used as the oxidizing reactant gas.

Next, the remaining oxidizing reactant gas that has not reacted with the metal precursor may be purged (S60).

By sequentially performing the steps of supplying the metal precursor (S30), purging (S40), supplying the reactant (S50), and purging (S60), the metal oxide layer 14 (e.g., the molybdenum oxide layer) may be formed in atomic layer units on the growth region 10 relative to the non-growth region 12. The steps of supplying the metal precursor (S30) and supplying the reactant (S50) may be performed alternately and sequentially. In order to form the metal oxide layer 14 of a desired thickness on the growth region 10, the steps of supplying the metal precursor (S30), purging (S40), supplying the reactant (S50), and purging (S60) may be performed in multiple times, for example, N cycles (N is a natural number).

In addition, as shown in FIG. 2, the steps of adsorbing the growth inhibitor (S10) and purging (S20) may be repeatedly performed for M cycles as one sub-cycle, and then the steps of supplying the metal precursor (S30), purging (S40), supplying the reactant (S50), and purging (S60) may be repeatedly performed for N cycles as another sub-cycle, and then the M cycles and the N cycles may be performed for P cycles as one super-cycle.

On the other hand, in a step of forming the metal oxide layer 14 on the growth region 10, a trace amount of Si component that may be derived from the Si-based growth inhibitor precursor may remain on the surface of the growth region 10. In some embodiments, the content of the Si component remained between the surface of the growth region 10 and the metal oxide layer 14 in the growth region 10 may increase when the growth inhibitor 13 is formed using the Si-based growth inhibitor precursor compared to when the growth inhibitor 13 is formed without using the Si-based growth inhibitor precursor. In some embodiments, when the growth region 10 includes TiN, the SiTiON layer may be formed between the surface of the growth region 10 and the metal oxide layer 14.

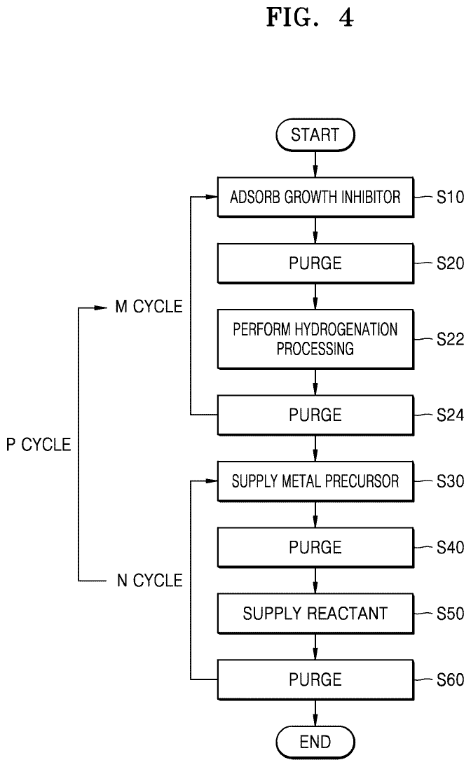

FIG. 4 is a schematic flowchart to explain a method of manufacturing a semiconductor device according to some other embodiments. The method of manufacturing the semiconductor device according to FIG. 4 may be different from the method of manufacturing the semiconductor device according to FIG. 2 in that a step of performing hydrogenation processing may be further performed on the adsorbed growth inhibitor and a surface reactor after performing the step of adsorbing the growth inhibitor. Hereinafter, descriptions that overlap the descriptions with respect to FIG. 2 will be omitted as much as possible.

Referring to FIG. 4 together with FIGS. 1A to 1C, after providing the base substrate 1 within the reaction space (not shown), the growth inhibitor 13 may be selectively adsorbed on the non-growth region 12 containing SiO₂ relative to the growth region 10 containing TiN using TCPS (C₆H₅Cl₃Si) as a Si-based growth inhibitor precursor. A SiO₂ surface may have a hydrophilic property that is terminated with —OH groups. When TCPS is adsorbed on the SiO₂ surface, two Si—Cl bonds may be broken and bonded on the SiO₂ surface, and the chemical state may be such that Cl atoms may remain even after the reaction thereof. At this time, since the Cl atom has a higher electronegativity than Si, the Cl atom may has a partial negative charge, which may cause a low water contact angle, and may act as an adsorption site where a metal precursor, for example, a molybdenum precursor, which is subsequently supplied to the reaction space may be adsorbed. That is, the molybdenum precursor may be adsorbed on the non-growth region 12, which may decrease a deposition selectivity of a metal oxide layer, for example, a molybdenum oxide layer.

In some embodiments, in order to improve the deposition selectivity of the metal oxide layer, a step of performing hydrogenation processing (S22) may be further performed on the adsorbed growth inhibitor 13 and a surface reactor after performing the step of adsorbing the growth inhibitor (S10). As described above with respect to FIG. 1B, in some embodiments, the hydrogenation processing may be performed before adsorbing the growth inhibitor 13. In some embodiments, the hydrogenation processing may be performed both before and after adsorbing the growth inhibitor 13 thereon. Specifically, after performing the step of adsorbing the growth inhibitor (S10), the remaining Si-based growth inhibitor precursor that is not adsorbed within the reaction space may be purged with a purge gas (S20), and then the hydrogenation processing may be performed while supplying a reducing gas within the reaction space. In some embodiments, the hydrogenation processing may be performed using H₂ gas, CCP H₂ plasma, ICP H₂ plasma, remote H₂ plasma, and the like.

In some embodiments, the step of performing the hydrogenation processing (S22) may be performed by exposing the base substrate 1 on which the growth inhibitor 13 is adsorbed to about 1000 sccm of about 99.999% hydrogen (H₂) gas in the reaction space at a pressure of about 10 torr for about 10 minutes. Next, the step of purging (S24) may be performed by supplying 1000 sccm of the argon gas to the reaction space for about 1 minute. In some embodiments, the step of hydrogenation processing (S22) may be performed in a temperature range of about 100° C. to about 400° C. In some embodiments, the step of hydrogenation processing (S22) may be performed at about 120° C., the same as the deposition temperature of the metal oxide layer 14 to be formed in the subsequent process. The step of absorbing the growth inhibitor (S10) and the step of performing the hydrogenation processing (S22) may be performed alternately and sequentially, and may be performed for M cycles. In this embodiment, the two steps were performed repeatedly 10 times.

After performing the step of adsorbing the growth inhibitor (S10), by the step of performing the hydrogenation processing (S22), the —OH groups on which TCPS is not absorbed on the SiO₂ surface may be reduced to the —H groups by hydrogen, which is a reducing gas. The molybdenum precursor to be supplied in the subsequent process may not be adsorbed on the —H group. At this time, the Cl atoms that remain on the SiO₂ surface after the adsorption of TCPS may also be removed. Accordingly, the —OH group, which may act as the adsorption site where the metal precursor, for example, the molybdenum precursor may be adsorbed on the SiO₂ surface in the subsequent process, may be reduced to the —H group, and the Cl atoms may be removed, so that the adsorption of the molybdenum precursor may hardly occur on the SiO₂ surface. As a result, the metal oxide layer 14 may be selectively grown on the growth region 10 relative to the non-growth region 12 where the growth inhibitor 13 is adsorbed, and thus a growth selectivity may be greatly improved.

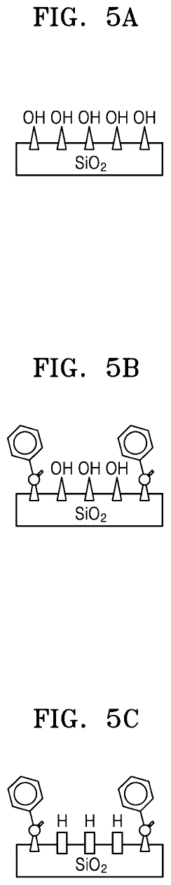

FIGS. 5A to 5C are conceptual diagrams illustrating changes in the surface state of a base substrate due to the hydrogenation processing during a method of manufacturing a semiconductor device according to some embodiments.

Referring to FIGS. 5A to 5C, FIG. 5A shows that the SiO₂ surface includes the hydrophilic property that is terminated with —OH group before the adsorption of the growth inhibitor. FIG. 5B shows a state in which TCPS of the growth inhibitors is adsorbed on the SiO₂ surface. TCPS is a compound of SiCl₃ containing a benzene ring, which may delay the adsorption of molybdenum precursors on the SiO₂ surface in the subsequent process due to the steric hindrance effect of TCPS itself. On the other hand, the WCA value after the adsorption of TCPS was measured at about 62.0 degrees. FIG. 5C shows a surface state after performing additional hydrogenation processing on the SiO₂ surface on which TCPS is adsorbed. On the other hand, the WCA value after the hydrogenation processing was measured at about 75.4 degrees. By additionally hydrogenating the —OH groups on the SiO₂ surface, which may act as adsorption sites for the molybdenum precursor in the subsequent process and substituting the —OH groups with Si—H, the adsorption sites for the molybdenum precursor may be reduced, so that the adsorption of the molybdenum precursor on the SiO₂ surface in the subsequent process may be limited, delayed, or prevented. In addition, during the hydrogenation processing, the remaining Cl atoms that may act as the adsorption sites for the molybdenum precursor in the subsequent process may also be removed to reduce the adsorption sites for the molybdenum precursor, so that the adsorption of the molybdenum precursor on the SiO₂ surface in the subsequent process may be limited, delayed, or prevented.

Referring to again FIG. 4, after repeating the steps of adsorbing the growth inhibitor (S10) and performing the hydrogenation processing (S22) for M cycles, the steps of supplying the metal precursor (S30) and purging (S40), and supplying the reactant (S50) and purging (S60) may be repeated for N cycles. In addition, after performing M cycles and N cycles, respectively, by repeating the P cycle multiple times as a super-cycle including the M cycle and the N cycle as sub-cycles, the metal oxide layer 14 may be selectively grown to the desired thickness on the growth region 10. On the other hand, as described above, in the step of forming the metal oxide layer 14 on the growth region 10, a trace amount of Si component that may be derived from the Si-based growth inhibitor precursor may remain on the surface of the growth region 10. In some embodiments, the content of the Si component remained between the surface of the growth region 10 and the metal oxide layer 14 in the growth region 10 may increase when the growth inhibitor 13 is formed using the Si-based growth inhibitor precursor compared to when the growth inhibitor 13 is formed without using the Si-based growth inhibitor precursor. In some embodiments, when the growth region 10 includes TiN, the SiTiON layer may be formed between the growth region 10 and the metal oxide layer 14.

Hereinafter, with reference to FIG. 4, a variety of embodiments in which the molybdenum oxide layer 14 may be selectively growing on the TiN surface of the growth region 10 compared to the SiO₂ surface of the non-growth region 12.

In some embodiments, as a first step, SiPhCl₃ as a growth inhibitor precursor may be supplied into a reaction space for 1 second, reacted for 300 seconds, and purged for 300 seconds. The first step above may be performed one or more times to selectively adsorb the growth inhibitor on the SiO₂ surface. Next, as a second step, for example, Mo(NMeEt)4 Molybdenum precursor may be supplied into the reaction space for 0.5 seconds and purged for 40 seconds. Next, as a third step, O₂ may be supplied into the reaction space for 1 second and purged for 20 seconds. The second and third steps may be repeated 30 times to selectively grow the molybdenum oxide layer with a thickness of 10 angstroms or less on the TiN surface.

In some embodiments, as a first step, (CH₃)₃SiN(CH₃)₂ as the growth inhibitor precursor may be supplied in the reaction space for 0.2 seconds, reacted for 60 seconds, and purged for 60 seconds. The first step above may be performed one or more times to selectively adsorb the growth inhibitor on the SiO₂ surface. Next, as a second step, Mo(NMeEt)₄ Molybdenum precursor may be supplied into the reaction space for 0.5 seconds and purged for 40 seconds. Next, as a third step, O₂ may be supplied into the reaction space for 1 second and purged for 20 seconds. The second and third steps may be repeated 30 times to selectively grow the molybdenum oxide layer with a thickness of 10 angstroms or less on the TiN surface.

In some embodiments, as a first step, SiPhCl₃ as the growth inhibitor precursor may be supplied into the reaction space for 1 second, reacted for 300 seconds, and purged for 300 seconds. The first step above may be performed one or more times to selectively adsorb the growth inhibitor on the SiO₂ surface. Next, as a second step, H₂ gas may be supplied into the reaction space for 600 seconds and purged for 60 seconds. Next, as a third step, Mo(NMeEt)₄ Molybdenum precursor may be supplied into the reaction space for 0.5 seconds and purged for 40 seconds. Next, as a fourth step, O₂ may be supplied into the reaction space for 1 second and purged for 20 seconds. The third and fourth steps may be repeated 30 times to selectively grow the molybdenum oxide layer with a thickness of 10 angstroms or less on the TiN surface.

In some embodiments, as a first step, (CH₃)₃SiN(CH₃)₂ as the growth inhibitor precursor compound may be supplied in the reaction space for 0.2 seconds, reacted for 60 seconds, and purged for 60 seconds. The first step above may be performed one or more times to selectively adsorb the growth inhibitor on the SiO₂ surface. Next, as a second step, H₂ gas may be supplied into the reaction space for 600 seconds and purged for 60 seconds. Next, as a third step, Mo(NMeEt)₄ Molybdenum precursor may be supplied into the reaction space for 0.5 seconds and purged for 40 seconds. Next, as a fourth step, O₂ may be supplied into the reaction space for 1 second and purged for 20 seconds. The first to fourth steps may be repeated 30 times to selectively grow the molybdenum oxide layer with a thickness of 10 angstroms or less on the TiN surface.

In some embodiments, as a first step, SiPhCl₃ as the growth inhibitor precursor compound may be supplied into the reaction space for 1 second, reacted for 300 seconds, and purged for 300 seconds. The first step above may be performed one or more times to selectively adsorb the growth inhibitor on the SiO₂ surface. Next, as a second step, H₂ gas may be supplied into the reaction space for 600 seconds and purged for 60 seconds. Next, as a third step, Mo(NMeEt)₄ Molybdenum precursor may be supplied into the reaction space for 1 second and purged for 40 seconds. Next, as a fourth step, O₂ may be supplied into the reaction space for 1 second and purged for 20 seconds. The first to fourth steps may be repeated 30 times to selectively grow the molybdenum oxide layer with a thickness of 10 angstroms or less on the TiN surface.

In some embodiments, as a first step, (CH₃)₃SiN(CH₃)₂ as the growth inhibitor precursor compound may be supplied in the reaction space for 1 second, reacted for 300 seconds, and purged for 300 seconds. The first step above may be performed one or more times to selectively adsorb the growth inhibitor on the SiO₂ surface. Next, as a second step, H₂ gas may be supplied into the reaction space for 600 seconds and purged for 60 seconds. Next, as a third step, Mo(NMeEt)₄ Molybdenum precursor may be supplied into the reaction space for 1 second and purged for 40 seconds. Next, as a fourth step, O₂ may be supplied into the reaction space for 1 second and purged for 20 seconds. The third and fourth steps may be repeated 30 times to selectively grow the molybdenum oxide layer with a thickness of 10 angstroms or less on the TiN surface.

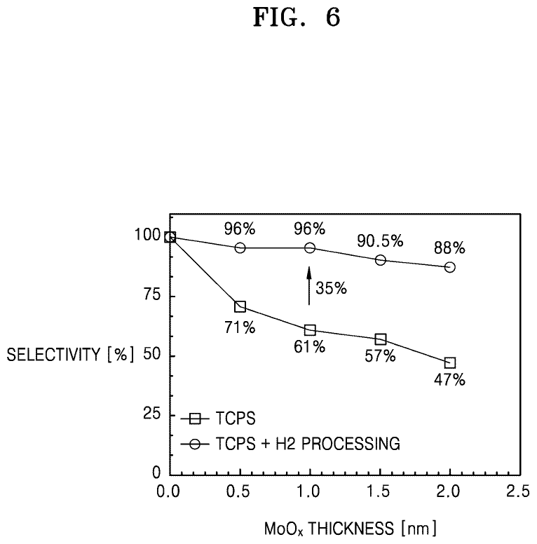

FIG. 6 is a graph illustrating the growth selectivity as a result of applying a method of manufacturing a semiconductor device according to some embodiments.

Referring to FIG. 6, the atomic layer deposition method was performed multiple cycles on a base substrate in which a TiN surface and a SiO₂ surface are exposed, respectively, and it was shown that a molybdenum oxide (MoOₓ) layer was selectively grown on the TiN surface relative to the SiO₂ surface. In FIG. 6, hollow square marks (Q) represent the growth selectivity of the molybdenum oxide layer on the TiN surface relative to the SiO₂ surface after respectively performing 25 cycles, 50 cycles, 75 cycles, and 100 cycles of the adsorption of TCPS on the SiO₂ surface and purge, in which TCPS was used as the growth inhibitor, based on the flowchart of FIG. 2. In FIG. 6, hollow circle marks (o) represent the growth selectivity of the molybdenum oxide layer on the TiN surface relative to the SiO₂ surface after respectively performing 25 cycles, 50 cycles, 75 cycles, and 100 cycles of the adsorption of TCPS on the SiO₂ surface, purge, hydrogenation processing, and purge, based on the flowchart of FIG. 4.

In FIG. 6, the horizontal axis represents the thickness of the molybdenum oxide layer (MoOₓ) grown on the TiN surface, and the thicknesses of the molybdenum oxide layer of 0.5 nm, 1.0 nm, 1.5 nm, and 2.0 nm correspond to results of performing the above 25 cycles, 50 cycles, 75 cycles, and 100 cycles, respectively. For example, when 50 cycles of atomic layer deposition method were performed based on the flowchart of FIG. 2, the growth selectivity of the molybdenum oxide layer on the TiN surface compared to the SiO₂ surface was 61%, whereas when 50 cycles of atomic layer deposition method were performed based on the flowchart of FIG. 4, the growth selectivity of the molybdenum oxide layer on the TiN surface compared to the SiO₂ surface was 96%, showing that the growth selectivity significantly increased by about 35%.

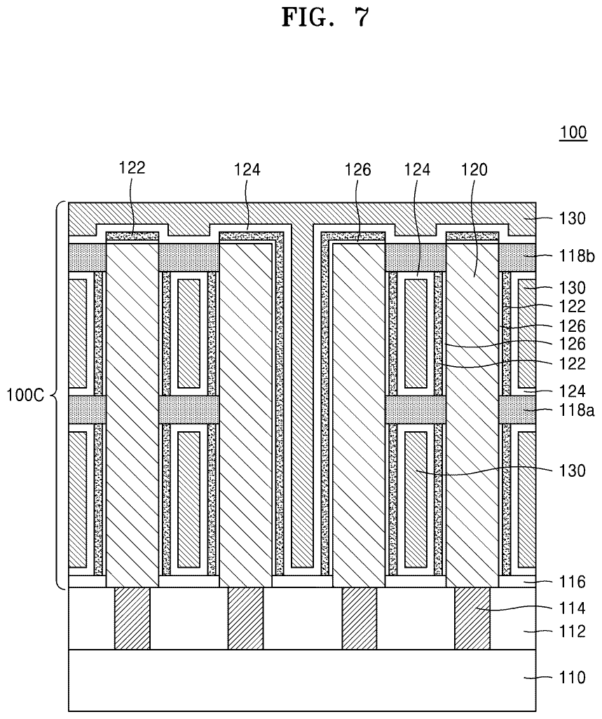

FIG. 7 is a cross-sectional view of a semiconductor device 100 formed according to a method of manufacturing a semiconductor device according to some embodiments. FIG. 7 is a cross-sectional view of a metal-insulator-metal (MIM) capacitor structure of a dynamic random access memory (DRAM) device in which the method of manufacturing the semiconductor device according to some embodiments is applied.

Referring to FIG. 7, the semiconductor device 100 may include a capacitor 100C formed on a substrate 110. The capacitor 100C may include a lower electrode 120, an upper electrode 130, and a dielectric layer 124 between the lower electrode 120 and the upper electrode 130. In addition, the capacitor 100C may further include an interface layer 122 between the lower electrode 120 and the dielectric layer 124. The lower electrode 120 may be electrically connected to a conductive portion (not shown) within the substrate 110 through a contact plug 114 that penetrates an interlayer insulating layer 112.

In addition, as the integration degree of the semiconductor device 100 increases, the aspect ratio of a pattern of the lower electrode 120 may become very large, and thus, there is a concern that the collapse of the lower electrode 120 may occur. Therefore, to avoid the collapse of the lower electrode 120, first and second supports 118a and 118b that may support the lower electrodes 120 from each other may be formed.

On the other hand, the upper electrode 130 may be formed on side walls and upper portions of the lower electrode 120 with the interface layer 122 and the dielectric layer 124 therebetween. A silicon-containing intervening layer 126 may be formed between the lower electrode 120 and the interface layer 122. In addition, an etching stop layer 116 surrounding the lower electrode 120 may be formed near a lower portion of the lower electrode 120.

The substrate 110 may include a material suitable for a semiconductor process. For example, the substrate 110 may include a semiconductor substrate, and the semiconductor substrate may include a material containing silicon. The semiconductor substrate may include silicon, single crystal silicon, polysilicon, amorphous silicon, silicon germanium, single crystal silicon germanium, polycrystalline silicon germanium, carbon-doped silicon, combinations thereof, or multilayers thereof. The semiconductor substrate may also include other semiconductor materials, such as germanium. The semiconductor substrate may also include a group III/V semiconductor substrate, such as a compound semiconductor substrates such as GaAs. The semiconductor substrate may also include a silicon on insulator (SOI) substrate.

In FIG. 7, the lower electrode 120 is shown as having a pillar shape, but the lower electrode 120 may include a cylindrical shape or a combination of the cylindrical shape and the pillar shape. A bottom portion of the lower electrode 120 may be electrically connected to the contact plug 114 through the etching stop layer 116. Outer walls of the lower electrodes 120 may be supported by the first and second supporters 118a and 18b. The first and second supporters 118a and 18b may include a plate-like structure that is horizontally extended to support the neighboring lower electrodes 120. The Supporter may include one or more supporter. For example, the supporter may include multi-level insulating supporter. FIG. 7 illustrates the first and second supporters 118a and 118b of two levels, in which the first supporter 118a is positioned at a lower portion and the second supporter 118b is positioned at an upper portion. The first supporter 118a and the second supporter 118b may be vertically spaced apart from each other to support the outer walls of the lower electrodes 120. The first supporter 118a and the second supporter 118b may include the same material or different materials. The first supporter 118a and the second supporter 118b may include a nitride-based material. In some embodiments, the first supporter 118a and the second supporter 118b may include an oxide-based material. For example, the first supporter 118a and the second supporter 118b may include a silicon nitride, a silicon carbon nitride, or a silicon boron nitride, but are not limited thereto.

The lower electrode 120 may include polysilicon or a metal-based material. The metal-based material may include a metal, a metal nitride, a metal silicon nitride, a conductive metal oxide, a metal silicide, a precious metal, or combinations thereof. The lower electrode 120 may include at least one of a transition metal or a transition metal nitride, for example, Ti, TiN, TiSiN, Ta, TaN, TiAlN, W, WN, Ru, RuO₂, Ir, IrO₂, Pt, Mo, or combinations thereof.

The upper electrode 130 may include polysilicon, silicon germanium, metal, a metal nitride, a metal silicon oxide, a conductive metal oxide, a metal silicide, a precious metal, or combinations thereof. The upper electrode 130 may include at least one of Ti, TiN, TiSiN, Ta, TaN, TiAlN, W, WN, Ru, RuO₂, Ir, IrO₂, Pt, Mo, or combinations thereof. For example, the upper electrode 130 may be formed by stacking TiN, SiGe and WN in this order.

The dielectric layer 124 may include a high-k material having a higher dielectric constant than a silicon oxide. The high-k material may include HfO₂, ZrO₂, Al₂O₃, TiO₂, Ta₂O₅, Nb₂O₅, or SrTiO₃, but it is not limited thereto. In some embodiments, the dielectric layer 124 may include a composite layer containing two or more layers of the high-k materials.

In some embodiments, the dielectric layer 124 may include a zirconium oxide-based material having a good leakage current characteristics while sufficiently lowering the equivalent oxide thickness (EOT). In some embodiments, the dielectric layer 124 may include a hafnium oxide having a tetragonal crystalline phase. In some embodiments, the dielectric layer 124 may include a ferroelectric material, an anti-ferroelectric material, or a combination thereof. In some embodiments, the dielectric layer 124 may include HfZrO, Hf-rich HfZrO, Zr-rich HfZrO, or a combination thereof. In some embodiments, the dielectric layer 124 may include a high band gap material having a high band gap energy to improve leakage current characteristics. The high band gap material may include an aluminum oxide, a silicon oxide or a beryllium oxide.

The interface layer 122 may be formed between the lower electrode 120 and the dielectric layer 124, thereby increasing the dielectric constant of the dielectric layer 124 and decreasing the leakage current of the capacitor 100C. In addition, by introducing the interface layer 122 having a high work function, dielectric relaxation (D/R) characteristics and leakage current characteristics of the capacitor may be improved. In addition, when the interface layer 122 is in direct contact with the dielectric layer 124, it may induce a high dielectric constant due to the phase transition, thereby increasing the capacitance of the capacitor.

The interface layer 122 may include an insulating material. The interface layer 122 may be a single material layer or a multilayer material layer including different material layers. An area between the lower electrodes 120 and the first and second supporters 118a and 118b may have an interface layer-free structure in which no interface layer 122 is positioned. The interface layer 122 may play a role in boosting the dielectric constant of the dielectric layer 124. The dielectric layer 124 may have an increased dielectric constant due to the interface layer 122. For example, when the dielectric layer 124 is used alone, the dielectric layer 124 has the dielectric constant of about 60, but when the dielectric layer 124 and the interface layer 122 are in contact, the dielectric layer 124 may have the dielectric constant greater than 60. The interface layer 122 may act as a polarization enhancement layer that enhances polarization of the dielectric layer 124, and the dielectric constant of the dielectric layer 124 may increase by the enhanced polarization. The interface layer 122 may contain an insulating material, so the interface layer 122 may play a role in decreasing leakage current.

The interface layer 122 and the dielectric layer (124) may include different materials from each other. The interface layer 122 may include a first high-k dielectric material, and the dielectric layer 124 may include a second high-k dielectric material, wherein the first high-k dielectric material may be different from the second high-k dielectric material. The dielectric layer 124 may contain a first metal, and the interface layer 122 may contain a second metal. The first metal may be different from the second metal. The first metal may include at least one selected from hafnium, zirconium, aluminum and titanium. The second metal may include niobium (Nb), tantalum (Ta), titanium (Ti), yttrium (Y), vanadium (V), manganese (Mn), or molybdenum (Mo). The dielectric layer 124 may include a first metal oxide, and the interface layer 122 may include a second metal oxide. In another embodiment, the dielectric layer 124 may include the first metal oxide, and the interface layer 122 may include a second metal oxynitride. The dielectric layer 124 may include a hafnium oxide, a zirconium oxide, an aluminum oxide, a titanium oxide, or combinations thereof. The interface layer 122 may include a niobium-based material. The interface layer 122 may include a niobium oxide (Nb₂O₅), a niobium nitride (NbN), or a niobium oxynitride (NbON). The niobium nitride (NbN) as the interface layer 122 may have insulating properties, and the niobium nitride having the insulating properties may include nitrogen-rich niobium nitride. In some embodiments, the interface layer 122 may include a high-k material, such as a tantalum oxide, a titanium oxide, an yttrium oxide, or a molybdenum oxide.

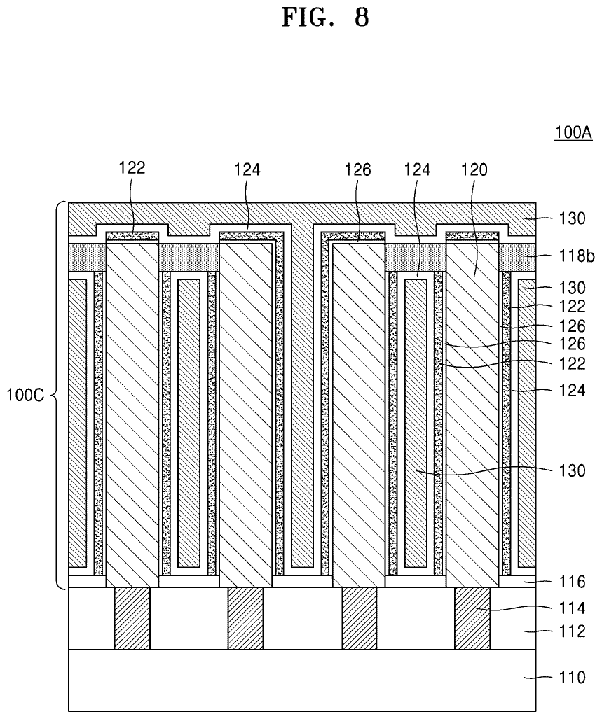

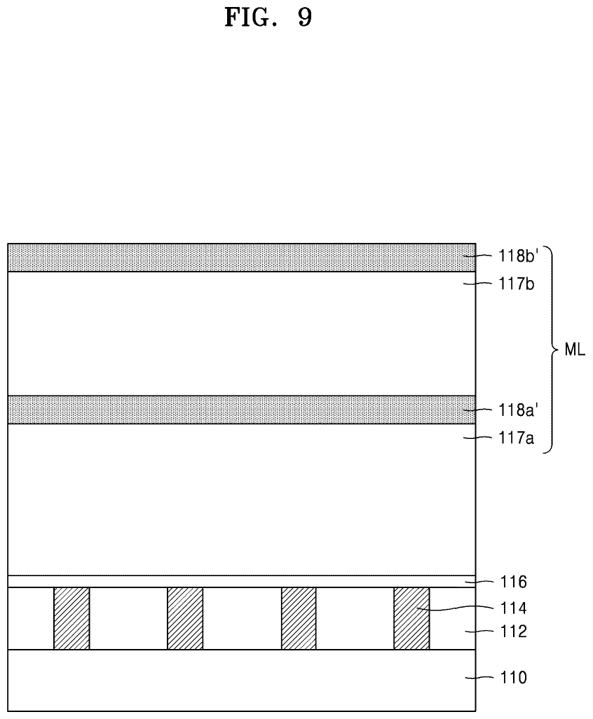

FIG. 8 is a cross-sectional view of a semiconductor device 100A formed according to a method of manufacturing a semiconductor device according to other embodiments. There is a difference in that the semiconductor device 100 of FIG. 7 may include two-layer level support in which a first support 118a is positioned at a lower level and a second supporter 118b is positioned at an upper level, respectively, but the semiconductor device 100A of FIG. 8 may include a single-layer level supporter 118b that is positioned only at the upper level. Hereinafter, descriptions that overlap the descriptions with respect to FIG. 7 will be omitted as much as possible.

Referring to FIG. 8, there is no first supporter 118a shown in FIG. 7 at the lower level, and therefore, the upper electrode 130 may extend vertically in correspondence to side walls of the lower electrode 120. This embodiment may be applied when a vertical height of the lower electrode 120 is relatively small.

FIGS. 9 to 17 are cross-sectional views sequentially shown to explain a method of manufacturing a semiconductor device according to some embodiments. Specifically, FIGS. 9 to 17 are cross-sectional views for explaining the method of manufacturing the semiconductor device 100 including the MIM capacitor as illustrated in FIG. 7.

Referring to FIG. 9, the interlayer insulating layer 112 may be formed on the substrate 110. The substrate 110 may include a semiconductor substrate, for example, a silicon (Si) substrate, a germanium (Ge) substrate, or a silicon-germanium (Si—Ge) substrate. The substrate may include specific circuit patterns therein, for example, patterns for constituting a transistor. In some embodiments, a plurality of word lines and bit lines may be formed on and/or within the substrate 110. In this case, the interlayer insulating layer 112 may be formed to cover the word lines and bit lines. In a DRAM device, source/drain regions (not shown) may be formed on both sides of each word line, and a contact plug 114 penetrating the interlayer insulating layer 112 may be connected to one of the source/drain regions.

The interlayer insulating layer 112 may include at least one of a silicon oxide, a silicon nitride, and a silicon oxynitride, but is not limited thereto. The contact plug 114 may include a semiconductor material, a metal, a metal nitride, a metal silicide, or combinations thereof. For example, the contact plug 114 may include polysilicon, tungsten, a tungsten nitride, a titanium nitride, a titanium silicon nitride, a titanium silicide, a cobalt silicide, or combinations thereof. In some embodiments, the contact plug 114 may be formed by stacking a semiconductor material, a metal silicide, a metal nitride, and a metal in that order.

The etching stop layer 116 may be formed on the interlayer insulating layer 112, and a mold structure ML may be formed on the etching stop layer 116. The etching stop layer 116 may include a silicon oxide, a silicon nitride, a silicon oxynitride, or a silicon carbon nitride. The mold structure ML may be a stack structure containing different insulating materials. For example, the mold structure ML may be formed on the etching stop layer 116 by stacking a first mold layer 117a, a first supporter forming material layer 118a′, a second mold layer 117b, and a second supporter forming material layer 118b′ in that order. On the other hand, when manufacturing the semiconductor device 100A illustrated in FIG. 8, the mold structure ML may include one mold layer and one supporter forming material layer (i.e., the second supporter forming material layer 118b′) on the etching stop layer 116.

The first supporter forming material layer 118a′ and the second supporter forming material layer 118b′ may include materials having an etching selectivity with respect to the first and second mold layers 117a and 117b. Additionally, the first supporter forming material layer 118a′ and the second supporter forming material layer 118b′ may include materials having the etching selectivity with respect to the etching stop layer 116. The first supporter forming material layer 118a′ and the second supporter forming material layer 118b′ may include a silicon nitride-based material. For example, the first mold layer 117a and the second mold layer 117b may include a silicon oxide, and the first supporter forming material layer 118a′ and the second supporter forming material layer 118b′ may include a silicon nitride (SiNₓ). In some embodiments, the first supporter forming material layer 118a′ and the second supporter forming material layer 118b′ may include a silicon oxynitride (SiON), a silicon carbon nitride (SiCN), a silicon oxycarbon nitride (SiOCN), or a silicon boron nitride (SiBN). In some embodiments, the first supporter forming material layer 118a′ and the second supporter forming material layer 118b may include a stack of a silicon nitride and a silicon carbon nitride, or a stack of a silicon nitride and a silicon boron nitride. The first supporter forming material layer 118a′ and the second supporter forming material layer 118b′ may include the same material, but in some embodiments, the first supporter forming material layer 118a′ and the second supporter forming material layer 118b′ may include different materials.

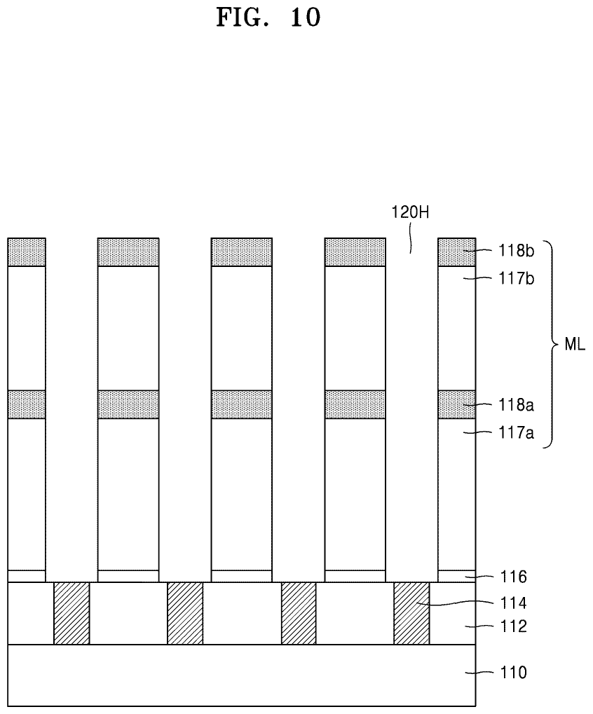

Referring to FIG. 10, a plurality of first openings 120H may be formed within the mold structure ML. The openings 120H may be formed using a mask (not shown) formed through a photolithography process. To form the first openings 120H, the second supporter forming material layer 118b′, the second mold layer 117b, the first supporter forming material layer 118a′, and the first mold layer 117a may be sequentially etched using the mask as an etching mask. An etching process for forming the first openings 120H may be stopped at the etching stop layer 116. The etching process for forming the first openings 120H may be performed using a dry etching process, a wet etching process, or a combination thereof. The first openings 120H may be locations at which lower electrodes may be formed in a subsequent process. Accordingly, the first supporter forming material layer 118a′ and the second supporter forming material layer 118b′ may become the first supporter 118a and the second supporter 118b, respectively, which support the lower electrodes formed within the first opening 120H in the subsequent process.

Next, the etching stop layer 116 that is exposed at a bottom of the first opening 120H may be removed under separate etching conditions to expose an upper surface of the contact plug 114. Depending on the size of a horizontal width of the first openings 120H, the entire upper surface of the contact plug 114 may be exposed, or only a portion of the upper surface may be exposed.

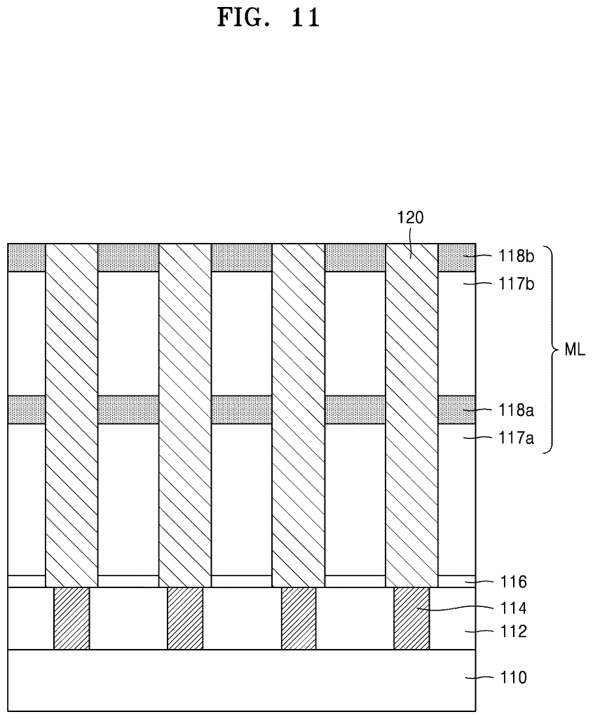

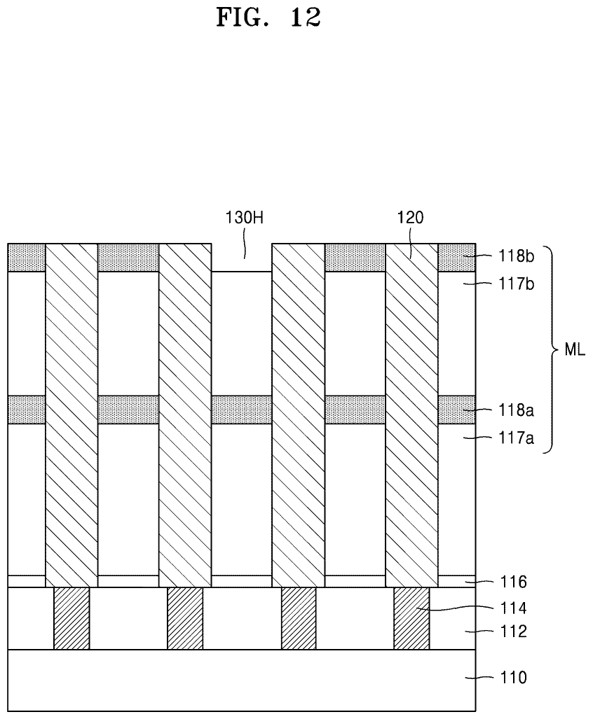

Referring to FIG. 11, the lower electrode 120 may be formed within each of the first openings 120H. The lower electrode 120 may have a pillar shape. In some embodiments, the lower electrode 120 may have a cylinder shape. In some embodiments, the lower electrode 120 may have a combination of the pillar shape and the cylinder shape. To form the lower electrode 120 having the pillar shape, a conductive material may be deposited to fill the first openings 120H and then a planarization process may be performed. The lower electrode 120 may include polysilicon or a metal-based material. The metal-based material may include a metal, a metal nitride, a metal silicon nitride, a conductive metal oxide, a metal silicide, a precious metal, or combinations thereof. The lower electrode 120 may include at least one of Ti, TiN, TiSiN, Ta, TaN, TiAlN, W, WN, Ru, RuO₂, Ir, IrO₂, Pt, Mo, or combinations thereof.

Referring to FIG. 12, a portion of the second supporter 118b may be etched to form a second opening 130H. A portion of an upper surface of the second mold layer 117b may be exposed through the second opening 130H. In addition, remaining portions of the second supporters 118b except for the etched portion for forming the second opening 130H may partially surround outer walls of the lower electrodes 120 and may limit and/or prevent the lower electrodes 120 from collapsing. One second supporter 118b may be in contact with the outer walls of at least two adjacent lower electrodes 120.

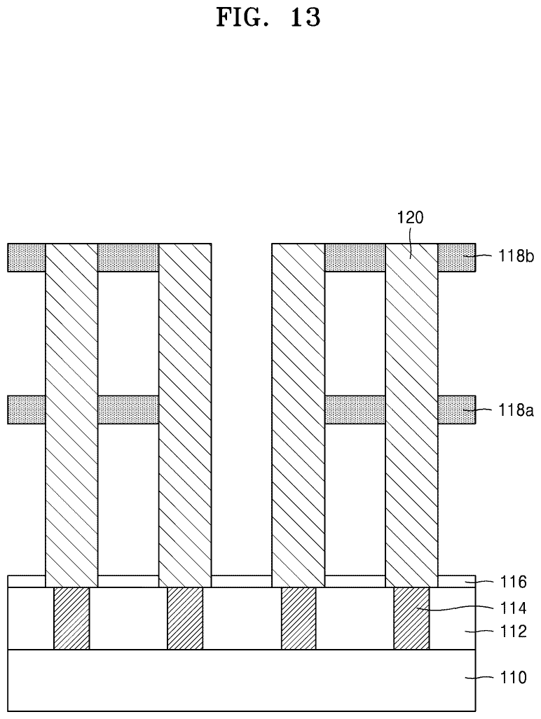

Referring to FIG. 13, the second mold layer 117b exposed by the second opening 130H may be removed by the etching process, for example, the wet etching process. The etching process for the second mold layer 117b may be performed using an etching solution having the etching selectivity with respect to the second supporter 118b. In some embodiments, when the second mold layer 117b includes a silicon oxide, the second mold layer 117b may be removed by the wet etching process using, for example, hydrofluoric acid (HF). At this time, not only the second mold layer 117b directly exposed under the second opening 130H, but also the second mold layer 117b between the adjacent lower electrodes 120 may be removed.

After removing the second mold layer 117b, a portion of the first supporter 118a exposed vertically below the second opening 130H may be etched and removed. By etching the portion of the first supporter 118a, an upper surface of the first mold layer 117a may be exposed. In addition, the first supporters 118a that remain without being etched may partially surround the outer walls of the lower electrodes 120 together with the second supporters 118b and limit and/or prevent the lower electrodes 120 from collapsing. One second supporter 118a may also be in contact with the outer walls of at least two adjacent lower electrodes 120.

Subsequently, the first mold layer 117a exposed under the first supporter 118a may be completely removed by the etching process, for example, the wet etching process. The etching process for the first mold layer 117a may be performed using an etching solution having the etching selectivity with respect to the first and second supporters 118a and 118b. In some embodiments, when the first mold layer 117a includes a silicon oxide, the first mold layer 117a may be removed by the wet etching process using, for example, hydrofluoric acid. The etching process for the first mold layer 117a may be performed until the etching stop layer 116 is exposed.

Meanwhile, the etching stop layer 116 may remain between the adjacent lower electrodes 120. In some embodiments, the etching stop layer 116 may be removed by a separate etching process.

As a result, as illustrated in FIG. 13, a structure that includes a plurality of lower electrodes 120 and a plurality of first and second supporters 118a and 118b that support the lower electrodes 120 may be formed on the substrate 110. In the structure including the lower electrode 120 illustrated in FIG. 13, portions of surfaces of the lower electrode 120, the first and second supporters 118a and 118b, and the etching stop layer 116 may be exposed. In some embodiments, when the etching stop layer 116 is removed, a surface of the interlayer insulating layer 112 may be exposed.

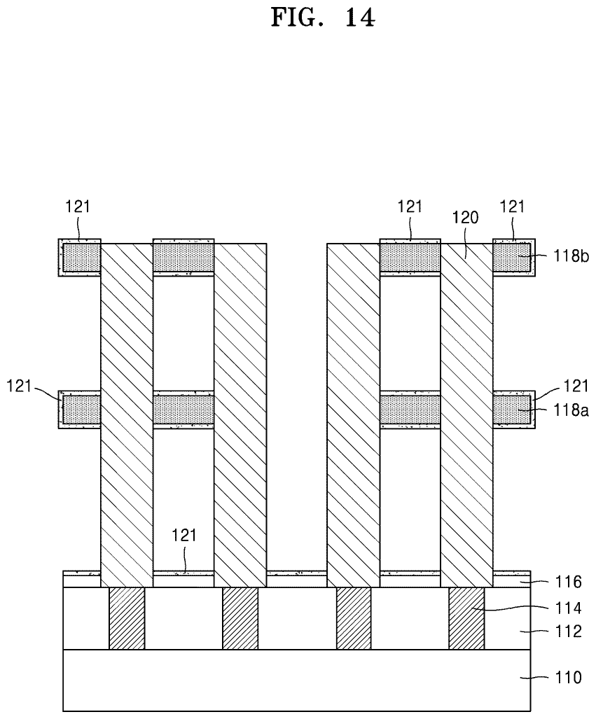

Referring to FIG. 14, after providing the structure of FIG. 13 within a reaction space, a growth inhibitor precursor may be supplied so that the growth inhibitor 121 is selectively adsorbed onto the exposed surfaces of the first and second supporters 118a and 118b relative to the exposed surfaces of the lower electrodes 120. A step of selectively adsorbing the growth inhibitor 121 may correspond to the step of adsorbing the growth inhibitor (S10) and the step of purging (S20) shown in FIGS. 2 and 4.

As described above with respect to FIGS. 1A to 1C, 2 and 4, the lower electrode 120 may correspond to the growth region 10, and the first and second supporters 118a and 118b may correspond to the non-growth region 12. Additionally, the etching stop layer 116 may also correspond to the non-growth region 12. When the etching stop layer 116 is removed, the interlayer insulating layer 112 can also correspond to the non-growth region 12. The growth region may be a region in which an interface layer and a dielectric layer may be grown according to a subsequent process in a MIM capacitor structure. The non-growth region may include a region where an interface layer and a dielectric layer are not grown according to a subsequent process.

The SMI precursor may be supplied within the reaction space to selectively adsorb the growth inhibitor 121 onto the exposed surfaces of the first and second supporters 118a and 118b and the exposed surface of the etching stop layer 116. In some embodiments, the growth inhibitor precursor may include a Si-based growth inhibitor precursor, such as SiPhCl₃, but is not limited thereto.

In some embodiments, the Si-based growth inhibitor precursor may include Si (CH₃) 3 (NMe₂), (CH₃)₃SiN (CH₃) 2, SiMe₃ (NMe₂), SiMe₃OEt, or SiMe₃OMe, in addition to SiPhCl₃. In some embodiments, the Si-based growth inhibitor precursor may include SiAₓB_{y}C_{z}Dₘ, wherein the SiAₓB_{y}C_{z}Dₘ may include one or more leaving groups and one or more inert ligands of A, B, C, and D ligands. The leaving group may include —Cl, —Br, —I, —O—R, —N—R₂, —OH, —NH₂, —SH, and the like. The inert ligand may include —R, cyclopentadienyl, phenyl, benzyl, benzonyl, and the like. On the other hand, in some embodiments, the growth inhibitor precursor may include acetylacetone, alcohol, and the like.

The Si-based growth inhibitor precursor may be hardly adsorbed on the exposed surfaces of the lower electrodes 120, which is the growth region. However, a trace amount of the Si-based growth inhibitor precursor may be adsorbed on the exposed surfaces of the lower electrodes 120, and thus a trace amount of Si component may remain. Next, a purge gas, for example, an argon gas, may be supplied into the reaction space to purge any unadsorbed Si-based growth inhibitor precursor that remains in the reaction space.

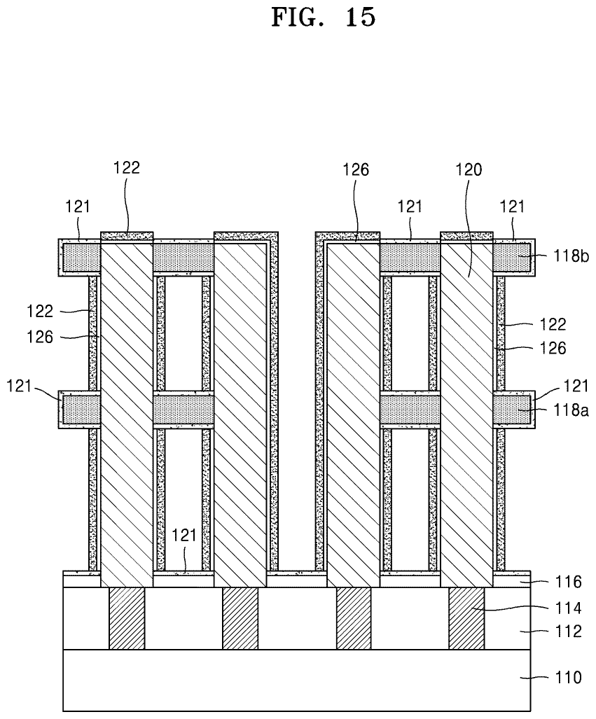

On the other hand, the adsorption of the growth inhibitor and the purging of the unadsorbed growth inhibitor precursor may be performed by the atomic layer deposition method. Therefore, the growth inhibitor 121 may be adsorbed in atomic layer units, so the supply of the growth inhibitor and the purge of the unadsorbed growth inhibitor precursor may be performed repeatedly multiple times, for example, for M cycles. In some embodiments, after the supplies and purge of the growth inhibitor precursor are performed for M cycles, the interface layer 122 in FIG. 15 may be formed on the exposed surfaces of the lower electrodes 120 on which the growth inhibitor 121 is not adsorbed, through the supplies of a metal precursor and a reactant into the reaction space.

On the other hand, as illustrated in FIG. 4, after the supply and purge of the growth inhibitor precursor are performed for M cycles, the hydrogenation processing may be further performed on the subsequently adsorbed growth inhibitor 121 or on a structure on which the growth inhibitor 121 is adsorbed on the first and second supporters 118a and 118b.

As described above with respect to FIGS. 1B and 4, in some embodiments, the hydrogenation processing may be performed before the adsorption of the growth inhibitor 121. In some embodiments, the hydrogenation processing may be performed both before and after the adsorption of the growth inhibitor 121 thereon. Additionally, after performing the step of adsorbing the growth inhibitor (S10), the Si-based growth inhibitor precursor that is not adsorbed within the reaction space may be purged with the purge gas, for example, the argon gas. The hydrogenation processing may be performed while supplying a reducing gas into the reaction space provided with the structure. In some embodiments, the hydrogenation processing may be performed using H₂ gas, CCP H₂ plasma, ICP H₂ plasma, remote H₂ plasma, and the like.

In some embodiments, the hydrogenation processing may be performed by exposing the structure having the growth inhibitor 121 thereon to about 1000 sccm of about 99.999% hydrogen (H₂) gas in the reaction space at a pressure of about 10 torr for about 10 minutes. Next, the reaction space may be purge by supplying 1000 sccm of argon gas for about 1 minute. In some embodiments, the hydrogenation processing may be performed in a temperature range of about 100° C. to about 400° C. In some embodiments, the hydrogenation processing may be performed at about 120° C., the same as a deposition temperature of the interface layer to be formed in the subsequent process. The step of absorbing the growth inhibitor and the step of hydrogenation processing may be performed alternately and sequentially, and may be performed repeatedly for M cycles, for example, 10 times.

By performing the step of hydrogenation processing after performing the step of absorbing the growth inhibitor, the —OH group on the surfaces of the first and second supporters 118a and 118b and/or the etching stop layer 116, on which that the Si-based growth inhibitor precursor is not adsorbed, may be reduced to —H group by hydrogen, which is a reducing gas. The adsorption of metal precursors to be supplied in the subsequent process may be limited on the —H group. In addition, in the step of hydrogenation processing, Cl atoms that remain on the surfaces of the first and second supporters 118a and 118b and/or the etching stop layer 116 after the Si-based growth inhibitor 121 is adsorbed may also be removed. Accordingly, the —OH group, which may act as an adsorption site for the metal precursor to be adsorbed for forming the interface layer 122 in the subsequent process, may be reduced to the —H group and the Cl atom may also be removed, so that the adsorption of the metal precursor may hardly occur on the surfaces of the first and second supporters 118a and 118b and/or the etching stop layer 116, except for the exposed surfaces of the lower electrodes 120. As a result, relatively little interfacial layer 122 may be formed on the surfaces of the first and second supporters 118a and 118b and/or the etching stop layer 116 compared to the exposed surfaces of the lower electrodes 120.

On the other hand, the adsorption of the growth inhibitor and the purge of the growth inhibitor precursor, and the hydrogenation processing and the purge thereof may be performed by the atomic layer deposition method. Accordingly, the growth inhibitor 121 may be adsorbed in atomic layer units, so the supply of the growth inhibitor and the hydrogenation processing may be performed repeatedly multiple times, for example, for M cycles.

Referring still further to FIG. 15, the interface layer 122 may be formed on the exposed surfaces of the lower electrodes 120 on which the growth inhibitor 121 is not adsorbed. The interface layer 122 may include a metal oxide layer. The interface layer 122 may be formed through the atomic layer deposition method. As illustrated in FIGS. 2 and 4, a step of forming the interface layer 122 may include a series of alternate and sequential steps of the supply of the metal precursor, purge, the supply of the reactant, and purge in the reaction space. When the interface layer 122 is a metal oxide layer, the metal precursor may be a raw material precursor of the metal oxide layer to be grown on the lower electrode 120, and may include, for example, a molybdenum precursor, a niobium precursor, a titanium precursor, a tantalum precursor, a vanadium precursor, a manganese precursor, or an yttrium precursor, but is not limited thereto. In this embodiment, the metal precursor may use the molybdenum precursor, but is not limited thereto. The molybdenum precursor may include a tetravalent precursor, a pentavalent precursor, or a hexavalent precursor. In some embodiments, the tetravalent molybdenum precursor may include MoAₓB_{y}C_{z}Dₘ (2≤x+y+z+m≤4, 0≤x, y, z, m≤4), MoAₓB_{y}C_{z}DₘEₙ (2≤x+y+z+m+n≤5, 0≤x, y, z, m, n≤5), or MoAₓB_{y}C_{z}DₘEₙFᵢ (2≤x+y+z+m+n+i≤6, 0≤x, y, z, m, n, i≤6), but is not limited thereto.

The reactant supplied into the reaction space may include, for example, an oxidizing reactant gas. The oxidizing reactant gas may include O₃, O₂, O₂ plasma, H₂O, NO₂, NO₂ plasma, N₂O, N₂O plasma, dry air, or alcohol, but is not limited thereto.

In order to form the interface layer 122 (e.g., a metal oxide layer) of a desired thickness on the lower electrodes 120, the supply of metal precursor, the purge, the supply of the reactant, and the purge may be performed multiple times, for example, or N cycles. In addition, the steps of adsorbing the growth inhibitor and the hydrogenation processing may be repeatedly performed for M cycles as one sub-cycle, and then the steps of supplying the metal precursor and supplying the reactant may be repeatedly performed for N cycles as another sub-cycle, and then the M cycles and the N cycles may be performed for P cycles as one super-cycle to form the interface layer 122 of a desired thickness on the lower electrode 120.

On the other hand, in the step of forming the interface layer 122 on the lower electrode 120, a trace amount of a Si-based growth inhibitor precursor may be adsorbed on the surface of the lower electrode 120. Accordingly, the Si-containing intervening layer 126 that contains a trace amount of Si component that is derived from the Si-based growth inhibitor precursor may be formed. Additionally, due to the Si-containing intervening layer 126, the content of Si on the surface of the lower electrode 120 may increase compared to a case in which the adsorption of the Si-based growth inhibitor and the hydrogenation processing are not performed. In some embodiments, when the lower electrode 120 is TiN, the Si-containing intervening layer 126 may include a SiTiON layer. The Si component of the Si-containing intervention layer 126 may limit and/or prevent oxidation of the surface of the lower electrode 120, thereby minimizing loss of the lower electrode 120.

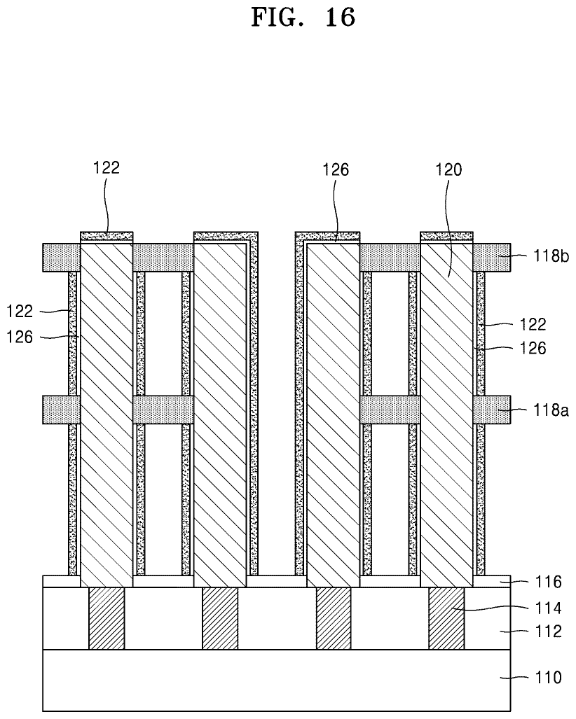

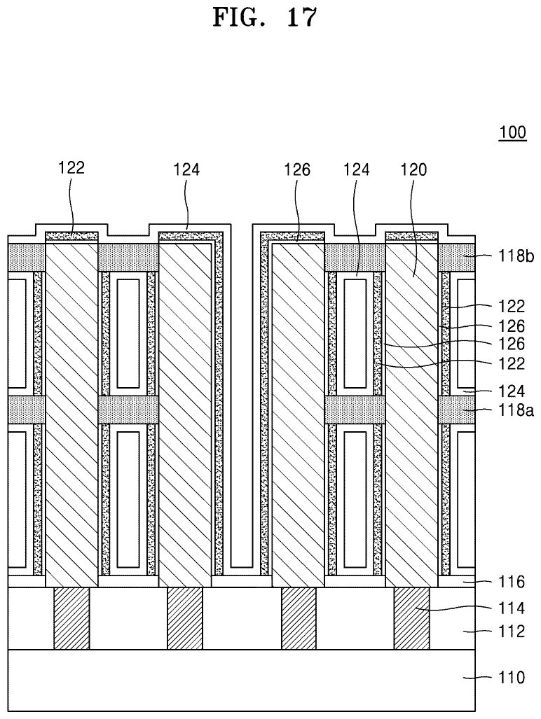

Referring to FIG. 16, the growth inhibitor 121 remaining on the exposed surfaces of the first and second supporters 118a and 118b and the etching stop layer 116 may be removed or oxidized. For example, ozone (O₃) may be supplied into the reaction space to oxidize the growth inhibitor 121 to eliminate the factor of leakage current of a capacitor.

Referring to FIG. 17, the dielectric layer 124 may be formed on the result of FIG. 16. The dielectric layer 124 may be formed not only on the exposed surface of the interface layer 122, but also on the exposed surfaces of the first and second supporters 118a and 118b and the etching stop layer 116. The dielectric layer 124 and the lower electrode 120 may not be in direct contact with each other due to the interface layer 122. The outer walls of the lower electrode 120 may be surrounded by the interface layer 122, and outer surfaces of the interface layer 122 may be surrounded by the dielectric layer 124.

The dielectric layer 124 may include a high-k material having a higher dielectric constant than a silicon oxide. The high-k material may include HfO₂, ZrO₂, Al₂O₃, TiO₂, Ta₂O₅, Nb₂O₅, or SrTiO₃, but it is not limited thereto. In some embodiments, the dielectric layer 23 may include a composite layer including two or more layers of the high-k material described above.

Next, referring again to FIG. 7, the upper electrode 130 may be formed on the dielectric layer 124. Accordingly, the semiconductor device 100 including the MIM capacitor may be obtained by the lower electrode 120, the interface layer 122 and the dielectric layer 124, and the upper electrode 130. The upper electrode 130 may fill spaces between adjacent lower electrodes 120 and extend to cover an upper portion of the lower electrode 120. The upper electrode 130 may include polysilicon, silicon germanium, metal, a metal nitride, a metal silicon oxide, a conductive metal oxide, a metal silicide, a precious metal, or combinations thereof. The upper electrode 130 may include at least one of Ti, TiN, TiSiN, Ta, TaN, TiAlN, W, WN, Ru, RuO₂, Ir, IrO₂, Pt, Mo, or combinations thereof. In some embodiments, the upper electrode 130 may be formed by stacking TiN, SiGe and WN in this order.

While inventive concepts have been particularly shown and described with reference to embodiments thereof, it will be understood that various changes in form and details may be made therein without departing from the spirit and scope of the following claims.

What is claimed is:

1. A method of manufacturing a semiconductor device, the method comprising:
preparing a base substrate in which surfaces of a growth region comprising TiN and a non-growth region comprising Si are each exposed;
adsorbing a Si-based growth inhibitor on the surface of the non-growth region by supplying the Si-based growth inhibitor to the base substrate; and
selectively forming a metal oxide layer on the growth region relative to the non-growth region by supplying a metal precursor and an oxidizing reactant gas to the base substrate,
wherein the selectively forming the metal oxide layer on the growth region includes forming a SiTiON layer between the surface of the growth region and the metal oxide layer.

2. The method of claim 1, further comprising:
after the adsorbing the Si-based growth inhibitor on the surface of the non-growth region, performing hydrogenation processing on the base substrate while the growth inhibitor is adsorbed on the surface of the of the non-growth region.

3. The method of claim 1, wherein the non-growth region comprises SiOₓ, SiNₓ, SiON, SiCN, or SiOCN.

4. The method of claim 1, wherein the Si-based growth inhibitor comprises SiPhCl₃, Si(CH₃)₃(NMe₂), (CH₃)₃SiN(CH₃)₂, SiMe₃(NMe₂), SiMe₃OEt, or SiMe₃OMe.

5. The method of claim 1, wherein
the metal oxide layer comprises a molybdenum oxide layer, a niobium oxide layer, a titanium oxide layer, a tantalum oxide layer, a vanadium oxide layer, a manganese oxide layer, or an yttrium oxide layer.

6. A method of manufacturing a semiconductor device, the method comprising:
forming a structure including a plurality of lower electrodes and a plurality of supporters on a base substrate, the plurality of supporters supporting the plurality of lower electrodes and being between the plurality of lower electrodes on the base substrate;
selectively adsorbing a Si-based growth inhibitor on exposed surfaces of the plurality of supporters relative to exposed surfaces of the plurality of lower electrodes;
performing hydrogenation processing on the structure while the Si-based growth inhibitor is selectively adsorbed on the exposed surfaces of the plurality of supporters;
selectively forming an interface layer on regions of the plurality of lower electrodes not covered by the plurality of supporters, the interface layer including a metal oxide layer;
forming a dielectric layer on the interface layer; and
forming an upper electrode on the dielectric layer.

7. The method of claim 6, wherein
the selectively adsorbing the Si-based growth inhibitor and the performing the hydrogenation processing on the structure are repeatedly performed.

8. The method of claim 6, wherein
the forming the interface layer comprises repeatedly performing the supplying a metal precursor in a reaction space in which the structure is provided and the supplying an oxidizing reactant gas into the reaction space multiple times.

9. The method of claim 6, wherein
the plurality of lower electrodes contain TiN, and
in the forming the interface layer, a SiTiON layer is formed between surfaces of the lower electrodes and the metal oxide layer.

10. The method of claim 6, wherein
the metal oxide layer comprises a molybdenum oxide layer, a niobium oxide layer, a titanium oxide layer, a tantalum oxide layer, a vanadium oxide layer, a manganese oxide layer, or an yttrium oxide layer.

11. The method of claim 6, further comprising,
after the forming the interface layer, oxidizing the Si-based growth inhibitor adsorbed on the supporters.

12. The method of claim 6, wherein the plurality of lower electrodes each comprise a transition metal or a transition metal nitride.

13. The method of claim 6, wherein
in the adsorbing the Si-based growth inhibitor on the exposed surfaces of the plurality of supporters, the Si-based growth inhibitor is also adsorbed on an exposed surface of the base substrate excluding the plurality of lower electrodes.

14. The method of claim 13, wherein
the plurality of supporters or a surface of the base substrate on which the Si-based growth inhibitor are adsorbed comprises SiOₓ, SiNₓ, SiON, SiCN, or SiOCN.

15. The method of claim 6, wherein
the Si-based growth inhibitor comprises SiPhCl₃, Si(CH₃)₃(NMe₂), (CH₃)₃SiN(CH₃)₂, SiMe₃(NMe₂), SiMe₃OEt, or SiMe₃OMe.

16. The method of claim 6, wherein
the Si-based growth inhibitor comprises SiAₓB_{y}C_{z}Dₘ, wherein
in SiAₓB_{y}C_{z}Dₘ, A, B, C, and D are ligands,
SiAₓB_{y}C_{z}Dₘ comprises at least one leaving group and at least one inert ligand among A, B, C, and D.

17. The method of claim 8, wherein
the metal precursor comprises a molybdenum precursor, and
the molybdenum precursor comprises MoAₓB_{y}C_{z}Dₘ, where 2≤x+y+z+m≤4, 0≤x, y, z, and m≤4,
the molybdenum precursor comprises MoAₓB_{y}C_{z}DₘEₙ, where 2≤x+y+z+m+n≤5, 0≤x, y, z, m, and n≤5, or
the molybdenum precursor comprises or MoAₓB_{y}C_{z}DₘEₙFᵢ, where 2≤x+y+z+m+n+i≤6, 0≤x, y, z, m, n, and i≤6.

18. The method of claim 8, wherein
the oxidizing reactant gas comprises O₃, O₂, O₂ plasma, H₂O, NO₂, NO₂ plasma, N₂O, N₂O plasma, dry air, or alcohol.

19. A method of manufacturing a semiconductor device, the method comprising:
providing a structure on a base substrate in a reaction chamber,
the structure including a plurality of lower electrodes and a plurality of supporters between the plurality of lower electrodes,
the plurality of lower electrodes including TiN,
the plurality of supporters supporting the plurality of lower electrodes, and
the plurality of supporters including SiOₓd, SiNₓ, SiON, SiCN or SiOCN;
adsorbing a Si-based growth inhibitor on surfaces of the plurality of supporters by supplying the Si-based growth inhibitor into the reaction chamber to provide the Si-based growth inhibitor to the structure on the base substrate,
the Si-based growth inhibitor including SiPhCl₃, Si(CH₃)₃(NMe₂), (CH₃)₃SiN(CH₃)₂, SiMe₃(NMe₂), SiMe₃OEt, or SiMe₃OMe;
performing hydrogenation processing on the structure on the base substrate while the Si-based growth inhibitor is adsorbed thereon by supplying a hydrogen-containing gas into the reaction chamber;
selectively forming an interface layer on regions of the plurality of lower electrodes not covered by the plurality of supporters,
the interface layer including a molybdenum oxide layer,
the selectively forming the interface layer including sequentially supplying a molybdenum precursor and an oxidizing reactant gas into the reaction chamber while the structure on the base substrate is in the reaction chamber, and
the selectively forming the interface layer including forming a SiTiON layer between the plurality of lower electrodes and the molybdenum oxide layer;
forming a dielectric layer on the interface layer; and
forming an upper electrode on the dielectric layer.

20. The method of claim 19, further comprising,
after the selectively forming the interface layer, oxidizing the Si-based growth inhibitor adsorbed on the plurality of supporters.
